(19) United States
(12) Patent Application Publication
(10) Pub. No.: US 2025/0137722 A1
(43) Pub. Date: May 1, 2025

(54) CHAMBER BODIES HAVING MACHINED LOWER WALLS, CHAMBER ARRANGEMENTS AND SEMICONDUCTOR PROCESSING SYSTEMS HAVING CHAMBER BODIES WITH MACHINED LOWER WALLS, AND METHODS OF MAKING CHAMBERS WITH MACHINED LOWER WALLS

(71) Applicant: ASM IP Holding B.V., Almere (NL)

(72) Inventors: Felix Rabinovich, Scottsdale, AZ (US); Terry Parde, Chandler, AZ (US); Gary Urban Keppers, Morgan Hill, CA (US); Amin Azimi, Phoenix, AZ (US); Alicia Almeda, Chandler, AZ (US); Fauhmee Oudeif, Phoenix, AZ (US)

(21) Appl. No.: 18/928,383

(22) Filed: Oct. 28, 2024

Related U.S. Application Data
(60) Provisional application No. 63/546,606, filed on Oct. 31, 2023.
(60) Provisional application No. 63/546,608, filed on Oct. 31, 2023.
(60) Provisional application No. 63/546,611, filed on Oct. 31, 2023.

(51) Int. Cl. F27B 17/00; B28B 11/02; B28D 1/02; B28D 1/14; B28D 1/18

(52) U.S. Cl. CPC F27B 17/0025; B28B 11/02; B28D 1/02; B28D 1/14; B28D 1/18

(57) ABSTRACT

A chamber body includes a ceramic weldment having an upper wall, a sidewall, and a lower wall. The upper wall is coupled to the sidewall by a sidewall-to-upper wall weld and includes an upper wall rib segment coupled to an upper wall plate by an upper wall rib segment weld. The sidewall is coupled to the lower wall by a sidewall-to-lower wall weld. The lower wall has a lower wall plate portion and a lower wall rib portion extending therefrom both formed from a singular ceramic workpiece using a subtractive manufacturing technique, the lower wall plate portion thereby defining a lower wall unwelded ribbed region including a plurality of lower wall rib segments defined by the lower wall rib portion of the lower wall. Chamber arrangements, semiconductor processing systems, and methods of making ceramic weldments for chamber bodies in chamber arrangement and semiconductor processing systems are also described.

### CROSS-REFERENCE TO RELATED APPLICATIONS

This application claims priority to and the benefits of U.S. Provisional Patent Application No. 63/546,606, U.S. Provisional Patent Application No., 63/546,608, and U.S. Provisional Patent Application 63/546,611, each filed on Oct. 31, 2023, the contents each of which are also incorporated herein by reference in their entirety.

### FIELD OF INVENTION

The present disclosure generally relates to chamber bodies, and more particularly to methods of making chamber bodies, such as chamber bodies formed at least in part from ceramic materials like quartz.

### BACKGROUND OF THE DISCLOSURE

Quartz articles, such as chambers employed to deposit material layers in semiconductor processing system, are commonly formed using welding techniques. For example, cold wall chambers used for material layer deposition using chemical vapor deposition techniques generally commonly include walls bounding a process space with structural members joined to the walls with welds. The structural elements are typically welded to the walls, such as using a hydrogen gas welding technique, enabling the process space contained within the chamber walls to be maintained at relative to low pressure relative to the external environment during material layer deposition onto substrates supported within the chamber.

One challenge to employing welded quartz articles is a tendency of the welding process to introduce artifacts into the chamber weldment during fabrication. For example, gas bubbles and/or inclusions formed non-native materials may infiltrate the weldment structure during welding, potentially altering the optical properties of the weldments and/or the strength of the weldment. The localized nature of the heating employed during the welding process and subsequent cooling may impart residual stress into the weldment structure, potentially limiting strength of the weldment and increasing risk that the weldment fracture during subsequent handling and/or fabrication processes. The heat employed during the welding process may distort shape of the weldment during welding in a way that departs dimensionally from the dimensions of the intended weldment, potentially altering properties of the resulting weldment.

Various countermeasures exist to limit the introduction of artifact into weldments and/or remove artifacts from weldments subsequent to the welding process. For example, welding may be accomplished in environmentally controlled workspaces to limit contaminant introduction.

The members being welded may further be cleaned prior to welding, also limiting risk that contaminant be introduced into the weldment during welding. Residual stress imparted by the welding process may be removed (at least in part) by annealing the weldment subsequent to the welding process, the uniform heating and subsequent controlled cooling limiting stress that could otherwise limit strength of the weldment. And heating of the articles being joined may be carefully controlled during the heating process to limit distortion of the shapes defined by resulting weldment, the weldment thereby more likely to satisfy the dimensional requirements of the application for which the weldment is to be employed. While generally satisfactory for its intended purpose, such techniques can add cost and complexity to the fabrication of quartz articles. For example, weldments formed from multiple welds may require multiple anneal operations due to the need to remove residual stress introduced during a prior welding operation prior to undergoing a subsequent welding operation, prolonging the fabrication process.

Such chambers and methods of making chambers using welding techniques have generally been considered suitable for their intended purpose. However, there remains a need in the art for improved chamber bodies, chamber arrangements and semiconductor processing systems including chamber bodies, and related methods of making chamber bodies. The present disclosure provides a solution to this need.

### SUMMARY OF THE DISCLOSURE

A chamber body is provided. A chamber body includes a ceramic weldment having an upper wall, a sidewall, and a lower wall. The upper wall is coupled to the sidewall by a sidewall-to-upper wall weld and includes an upper wall rib segment coupled to an upper wall plate by an upper wall rib segment weld. The sidewall is coupled to the lower wall by a sidewall-to-lower wall weld. The lower wall has a lower wall plate portion and a lower wall rib portion extending therefrom both formed from a singular ceramic workpiece using a subtractive manufacturing technique (e.g., is uncast), the lower wall plate portion thereby defining a lower wall unwelded ribbed region including a plurality of lower wall rib segments defined by the lower wall rib portion.

In addition to one or more of the features described above, or as an alternative, further examples of the chamber body may include that the upper wall rib segment of the ceramic weldment overlays the lower wall unwelded ribbed region of the lower wall of the ceramic weldment.

In addition to one or more of the features described above, or as an alternative, further examples of the chamber body may include that the upper wall rib segment weld of the ceramic weldment overlays the lower wall unwelded ribbed region of the lower wall of the ceramic weldment.

In addition to one or more of the features described above, or as an alternative, further examples of the chamber body may include that the ceramic weldment has an inject end flange coupled to the lower wall of the ceramic weldment and an exhaust end flange coupled to the lower wall of the ceramic weldment. The lower wall unwelded ribbed region of the lower wall of the ceramic weldment may separate the exhaust end flange of the ceramic weldment from the inject end flange of the ceramic weldment.

In addition to one or more of the features described above, or as an alternative, further examples of the chamber body, and more specifically the ceramic weldment, may include that the inject end flange may be coupled to the upper wall plate by an inject end flange-to-upper wall plate weld. The exhaust end flange may be coupled to the upper wall plate by an exhaust end flange-to-upper wall plate weld. The lower wall unwelded ribbed region of the lower wall of the ceramic weldment may separate the exhaust end flange-to-upper wall plate weld from the inject end flange-to-upper wall plate weld.

In addition to one or more of the features described above, or as an alternative, further examples of the chamber body may include that the lower wall unwelded ribbed region of the lower wall may longitudinally spans the inject end flange-to-upper wall plate weld and the exhaust end flange-to-upper wall plate weld.

In addition to one or more of the features described above, or as an alternative, further examples of the chamber body may include that the sidewall is a first sidewall and that the ceramic weldment further includes a second sidewall. The second sidewall may couple the lower wall to the upper wall. The lower wall unwelded ribbed region may laterally separates the second sidewall from the first sidewall.

In addition to one or more of the features described above, or as an alternative, further examples of the chamber body may include that the first sidewall may be coupled to the lower wall plate portion by a first sidewall-to-lower wall plate portion weld. The second sidewall may be coupled to the lower wall plate portion by a second sidewall-to-lower wall plate portion weld. The lower wall unwelded ribbed region of the lower wall of the ceramic weldment may couple the second sidewall-to-lower wall plate portion weld to the first sidewall-to-lower wall plate portion weld.

In addition to one or more of the features described above, or as an alternative, further examples of the chamber body may include that the upper wall rib segment laterally spans the first sidewall and the second sidewall.

In addition to one or more of the features described above, or as an alternative, further examples of the chamber body may include that the upper wall rib segment weld coupling the upper wall rib segment to the upper wall plate. The upper wall rib segment weld may laterally span the first sidewall-to-lower wall plate portion weld and the second sidewall-to-lower wall plate portion weld.

In addition to one or more of the features described above, or as an alternative, further examples of the chamber body may include that the lower wall unwelded ribbed region has a width that is greater than at least 300 millimeters.

In addition to one or more of the features described above, or as an alternative, further examples of the chamber body may include that the ceramic weldment consists of or consists essentially of quartz.

A chamber arrangement is provided. The chamber arrangement includes a chamber body as described above wherein the lower wall defines a passthrough and the ceramic weldment of the chamber body further has a tubulation body registered to the passthrough coupled thereto at the passthrough. A substrate support may be arranged within an interior of the chamber body and supported for rotation about a rotation axis extending through the passthrough, a support member arranged along rotation axis and fixed in rotation relative to the substrate support, and a shaft member arranged along the rotation axis and fixed in rotation relative to the support member. The shaft member extends through the passthrough and the tubulation body, the shaft member thereby operably coupling the substrate support a lift and rotate module.

In addition to one or more of the features described above, or as an alternative, further examples of the chamber arrangement may include that the substrate support may overlay the lower wall unwelded ribbed region. The chamber arrangement may further include a pyrometer optically coupled to substrate support by the lower wall unwelded ribbed region.

In addition to one or more of the features described above, or as an alternative, further examples of the chamber arrangement may include a lower heater element array including a lower heater element supported below the lower wall of the ceramic weldment. The lower wall unwelded ribbed region may optically couple the lower heater element to the substrate support.

In addition to one or more of the features described above, or as an alternative, further examples of the chamber arrangement may include that the sidewall is a first sidewall and the ceramic weldment further includes a second sidewall coupling the lower wall to the upper wall, an inject end flange coupled to the lower wall, and an exhaust end flange coupled to the lower wall. The lower wall unwelded ribbed region may laterally separates the second sidewall from the first sidewall. The lower wall unwelded ribbed region may separate the exhaust end flange from the inject end flange.

A semiconductor processing system is provided. The semiconductor processing system includes a chamber arrangement having a chamber body with a ceramic weldment as described above, the lower wall unwelded ribbed region of the ceramic weldment having a width that is greater than at least 300 millimeters. A precursor source including a silicon-containing material layer precursor may be coupled to an injection end of the chamber body and an exhaust source including a vacuum pump may be coupled to an exhaust end of the chamber body and therethrough to the precursor source.

A method of making a weldment for a chamber body is provided. The method includes forming a lower wall plate portion and a lower wall rib portion extending from the lower wall plate portion from a singular ceramic workpiece using a subtractive manufacturing technique. A sidewall is coupled to the lower wall with a sidewall-to-lower wall weld formed using a welding technique, an upper wall plate is coupled to the sidewall with a sidewall-to-upper wall weld formed using the welding technique, and an upper wall rib segment is coupled to the upper wall plate with an upper wall rib segment weld using the welding technique such that the lower wall plate has an unwelded ribbed region including two or more lower wall rib segments defined by the lower wall rib portion of the lower wall.

In addition to one or more of the features described above, or as an alternative, further examples of the method may include defining a passthrough within the lower wall plate portion coupling a lower wall interior surface with a lower wall exterior surface, the passthrough within the lower wall unwelded ribbed region and longitudinally bounded by two lower wall rib segments defined by the lower wall rib portion of the lower wall.

In addition to one or more of the features described above, or as an alternative, further examples of the method may include that the subtractive manufacturing technique includes at least one of milling, boring, and sawing.

A semiconductor processing system may have a chamber arrangement with a chamber body made using the above-described method.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system in accordance with the present disclosure, showing material layer being deposited onto a substrate while seated in a chamber arrangement including a chamber body with a ceramic weldment;

FIG. 2 is a cross-sectional side view of the chamber body of FIG. 1, showing a lower heater element array and a pyrometer optically coupled to an interior of the chamber body by a lower wall unwelded ribbed region of the ceramic weldment;

FIGS. 3-6 are plan and side elevation views of a ceramic weldment defining the chamber body of FIG. 1, showing an upper wall including weld coupling upper rib segments to an upper wall plate and the lower wall unwelded ribbed region of the ceramic weldment;

FIG. 7 is an exploded perspective view of the ceramic weldment defining the chamber body, schematically showing a lower wall rib portion and a lower wall plate portion being defined using a subtractive manufacturing technique; and

FIG. 8 is a process flow diagram of a method of making a ceramic weldment for a chamber body of a semiconductor processing system, showing operations of the method according to illustrative and non-limiting examples of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

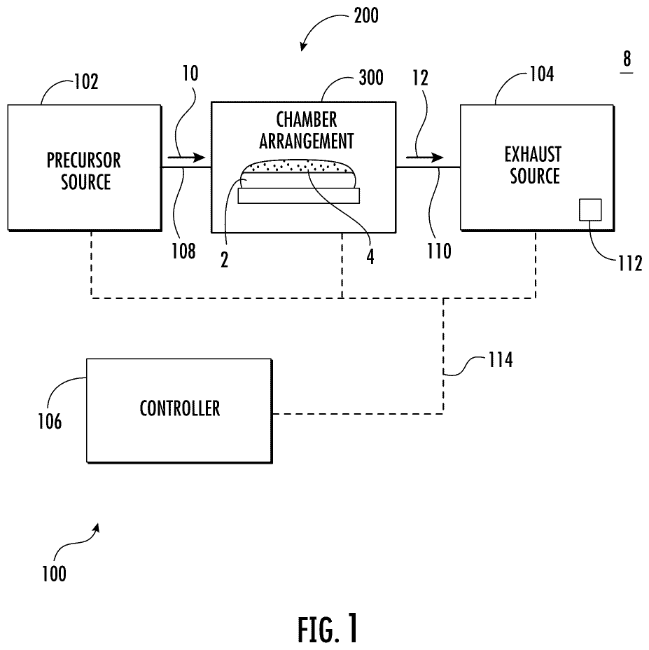

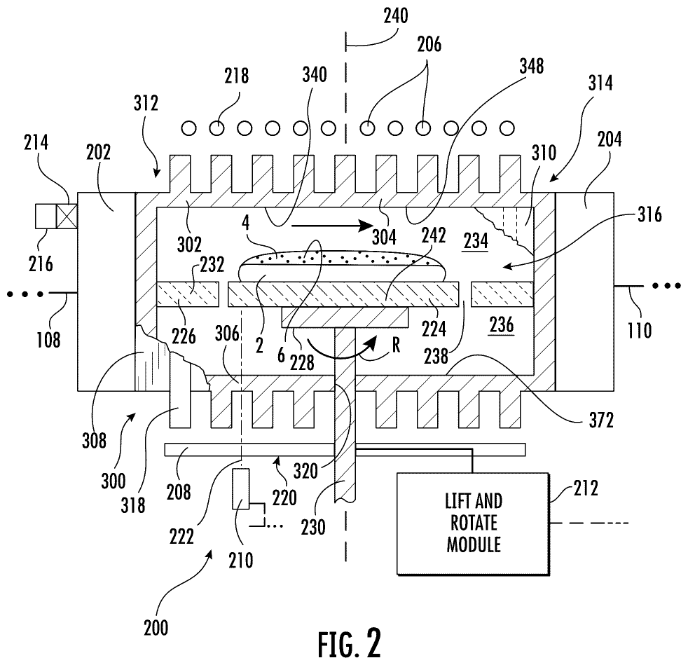

Reference will now be made to the drawings wherein like reference numerals identify similar structural features or aspects of the subject disclosure. For purposes of explanation and illustration, and not limitation, a partial view of an example of a semiconductor processing system including a chamber arrangement with a chamber body in accordance with the present disclosure is shown in FIG. 1 and is designated generally by reference character 100. Other examples of chamber bodies, chamber arrangements and semiconductor processing systems including chamber bodies in accordance with the present disclosure, and related methods a making chamber bodies and depositing material layers onto substrates supported in chamber bodies in accordance with the present disclosure, or aspects thereof, are provided in FIGS. 2-8, as will be described. The systems and methods of the present disclosure may be used to make and use chamber bodies employed to deposit material layers onto substrates, such as silicon-containing epitaxial material layers deposited using chemical vapor deposition techniques in chamber arrangements having crossflow architectures, thought the present disclosure is not limited to any particular deposition technique or chamber architecture in general.

Referring to FIG. 1, the semiconductor processing system 100 is shown. The semiconductor processing system 100 includes a precursor source 102, a chamber arrangement 200 including a chamber body 300, an exhaust source 104, and a controller 106. The precursor source 102 is connected to the chamber arrangement 200 by a precursor supply conduit 108 and is configured to provide a flow of a material layer precursor 10 to the chamber arrangement 200. The chamber arrangement 200 is connected to the exhaust source 104 and is configured to expose a substrate 2 supported within the chamber arrangement 200 under environmental conditions (e.g., temperature and pressure) selected to cause a material layer 4 to deposit onto an upper surface 6 of the substrate 2. The exhaust source 104 is connected to the chamber arrangement 200 by an exhaust conduit 110, is fluidly coupled to an external environment 8 outside of the semiconductor processing system 100 (e.g., through a vacuum pump 112 and/or an abatement device such as a scrubber), and is configured to communicate a flow of residual material layer precursor and/or reaction products 12 to the external environment 8.

It is contemplated that the controller 106 may be operably connected to one or more of the precursor source 102, the chamber arrangement 200, and the exhaust source 104 to control deposition of the material layer 4 onto the substrate 2. In this respect the controller 106 may be connected to one or more of the precursor source 102, the chamber arrangement 200, and the exhaust source 104 by a wired or wireless link 114 to control temperature of the substrate 2 and/or pressure within the chamber body 300. Temperature of the substrate 2 may be controlled, for example, using heater elements included in the chamber arrangement 200 and operatively associated with the controller 106. Pressure within the chamber body 300 may be controlled using the vacuum pump 112 included in the exhaust source 104.

In certain examples, the material layer precursor 10 may include one or more silicon-containing material layer precursor. Examples of suitable silicon-containing material layer precursor include non-halogenated silicon-containing material layer precursors, such as silane (SiH₄) and disilane (Si₂H₆), and halogenated silicon-containing material layer precursors, such as dichlorosilane (H₂SiCl₂) and trichlorosilane (HCl₃Si). In accordance with certain examples, the material layer precursor 10 may include an alloying constituent, such as germanium-containing material layer precursor such as germane (GeH₄), a gallium-containing material layer precursor such as triethylgallium Ga(C₂H₅)₃, or an indium-containing material layer precursor such as trimethylindium ((CH₃)₃In). It is contemplated that, in certain examples, the material layer precursor 10 may include one or more dopant-containing material layer precursor. Examples of suitable dopant-containing material layer precursors include p-type dopants like boron (B) and arsenic (As) as well as n-type dopants such as phosphorous (P) and antimony (Sb). It is contemplated that, in accordance with certain examples, the material layer precursor 10 may be co-flowed with a diluent/carrier gas such as hydrogen (H₂) gas or nitrogen (N₂) gas and/or with an etchant, such as hydrochloric (HCl) acid or chlorine (Cl₂) gas.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers. A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may be unpatterned, such as a so-called blanket-type substrate. As examples, substrates in the form of a powder may have applications for pharmaceutical manufacturing. A porous substrate may including one or more polymers. Examples of workpieces may include medical devices (for example, stents and syringes), jewelry, tooling devices, components for battery manufacturing (for example, anodes, cathodes, or separators) or components of photovoltaic cells, etc. A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

With reference to FIG. 2, the chamber arrangement 200 is shown. In the illustrated example the chamber arrangement 200 includes the chamber body 300, an injection flange 202, and an exhaust flange 204. In the illustrated example the chamber arrangement 200 also includes an upper heater element array 206, a lower heater element array 208, a pyrometer 210, and a lift and rotate module 212. Although shown and described herein as having certain elements and a specific architecture, e.g., a single substrate crossflow architecture, it is to be understood and appreciated that semiconductor processing systems having chamber arrangement including other elements and/or excluding elements shows and described herein, as well as having different architectures, may also benefit from the present disclosure.

The chamber body 300 is formed from a ceramic material 302 and has an upper wall 304, a lower wall 306, a first sidewall 308, and a second sidewall 310. The upper wall 304 extends longitudinally between an injection end 312 and a longitudinally opposite exhaust end 314. The lower wall 306 is spaced apart from the upper wall 304 by an interior 316 of the chamber body 300 and may be substantially parallel to the upper wall 304 of the chamber body 300. The first sidewall 308 couples the lower wall 306 of the chamber body 300 to the upper wall 304 of the chamber body 300, longitudinally spans the injection end 312 and the exhaust end 314 of the chamber body 300, and may be substantially orthogonal relative to either r (or both) the lower wall 306 and the upper wall 304 of the chamber body 300. The second sidewall 310 is similar to the first sidewall 308 and is additional laterally separated from the first sidewall 308 by a lateral width of the interior 316 of the chamber body 300. It is contemplated that the chamber body 300 may have a plurality of external ribs 318 extending laterally about the exterior surfaces of the upper wall 304, the lower wall 306, the first sidewall 308, and the second sidewall 310, and the plurality of external ribs 318 be longitudinally spaced apart from one another between the injection end 312 and the exhaust end 314 of the chamber body 300. It also contemplated that the injection flange 202 abut the injection end 312 of the chamber body 300 and couple the precursor supply conduit 108 to the chamber body 300, that the exhaust flange 204 abut the exhaust end 314 of the chamber body 300 and couple the chamber body 300 to the exhaust conduit 110, and the injection flange 202 couple a gate valve 214 and a substrate transfer robot 216 to the chamber body 300. In certain examples the ceramic material 302 may include a transparent material, such as a ceramic material transparent to electromagnetic radiation within an infrared waveband. Examples of suitable transparent materials include quartz, fused silica, and sapphire. In certain examples, the ceramic weldment 324 may consist of or consist essentially of the ceramic material 302, the ceramic weldment 324 consisting of or consisting essentially of quartz in certain examples of the disclosure. Although shown and described herein as having a particular number of external ribs 318, it is to be understood and appreciated that the chamber body 300 may have fewer or additional external ribs than shown and described herein and remain within the scope of the disclosure.

The upper heater element array 206 is configured to heat the substrate 2 during deposition of the material layer 4 onto the upper surface 6 of the substrate 2 (e.g., using electromagnetic radiation within an infrared waveband) and in this respect is supported above the chamber body 300, is optically coupled to the interior 316 of the chamber body 300 by the upper wall 304 of the chamber body 300, and includes a plurality of upper heater elements 218. The plurality of upper heater elements 218 may individually include linear filament, may extend laterally above the upper wall 304 of the chamber body 300 and between the first sidewall 308 and the second sidewall 310, and be longitudinally spaced apart from one another between the injection end 312 and the exhaust end 314 of the chamber body 300. The lower heater element array 208 may be similar to the upper heater element array 206, additionally be supported below the chamber body 300, and further include a plurality of lower heater elements 220. The plurality of lower heater elements 220 may extend longitudinally between the injection end 312 and the exhaust end 314 of the chamber body 300 and be laterally spaced apart from one another between the first sidewall 308 and the second sidewall 310 of the chamber body 300. In certain examples, the plurality of lower heater elements 220 may be substantially orthogonal relative to the plurality of upper heater elements 218. In accordance with certain examples, either (or both) the upper heater element array 206 and the lower heater element array 208 may include bull-type lamps and remain within the scope of the present disclosure.

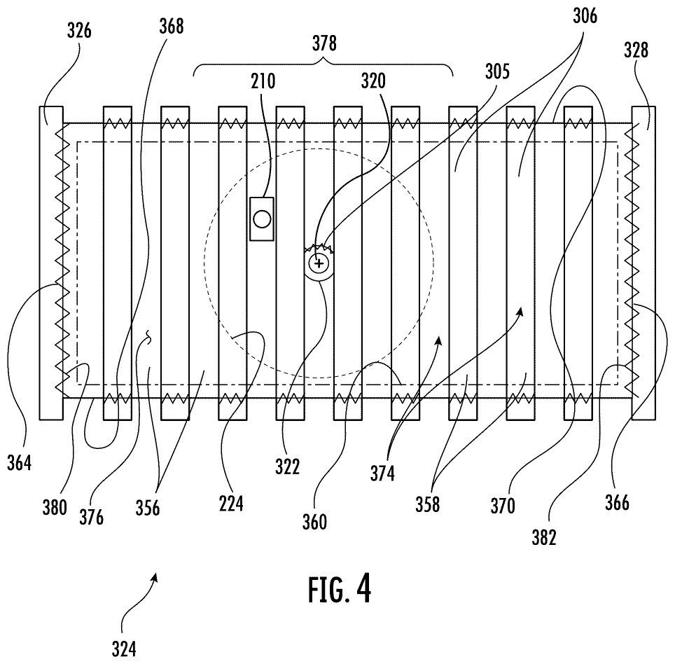

The pyrometer 210 is configured to acquire temperature measurements of the substrate 2 during deposition of the material layer 4 onto the upper surface 6 of the substrate 2 and in this respect may be supported below the chamber body 300. In this respect it is contemplated that the pyrometer 210 be arranged along an optical axis 222 intersecting a substrate support 224 arranged within the interior 316 of the chamber body 300 and configured to seat thereon the substrate 2, and optically coupled to the interior 316 of the chamber body 300 by the lower wall 306 of the chamber body 300, such as by a lower wall unwelded ribbed region 360 (shown in FIG. 4). Temperature measurements may be acquired using electromagnetic radiation emitted by either (or both) the substrate 2 and the material layer 4 during deposition onto the upper surface 6 of the substrate 2 and communicated through the ceramic material 302 forming the lower wall 306 of the chamber body 300 along the optical axis 222. In certain examples, the pyrometer 210 may cooperate with one or more second pyrometer supported above the upper wall 304 of the chamber body 300 and arranged along an optical axis intersecting the substrate support 224. In accordance with certain examples, the pyrometer 210 may cooperate with one or more chamber pyrometer, e.g., a pyrometer outside of the chamber body 300 and configured to acquire temperature of the ceramic material 302 using electromagnetic radiation emitted by the chamber body 300. Examples of suitable pyrometers include those shown and described in U.S. Patent Application Publication No. 2022/0298672 A1 to M'Saad, filed on Mar. 17, 2022, the contents of which are incorporated herein by reference in its entirety.

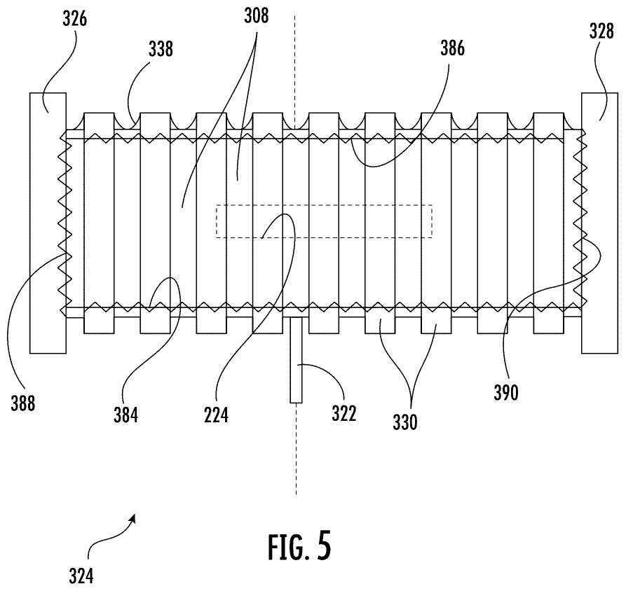

In the illustrated example the chamber arrangement 200 further includes a divider 226, a support member 228, and a shaft member 230. The divider 226 is formed from an opaque material 232, e.g., a material opaque to electromagnetic radiation within an infrared waveband, is seated within the interior 316 of the chamber body 300, divides the interior 316 into an upper chamber 234 and a lower chamber 236, and defines a divider aperture 238 therethrough coupling the upper chamber 234 to the lower chamber 236. The substrate support 224 is supported within the divider aperture 238 for rotation R about a rotation axis 240, may be formed from an opaque material 242, e.g., a material opaque to electromagnetic radiation within an infrared waveband, and is operably associated with the lift and rotate module 212 via the support member 228 and the shaft member 230. In this respect the support member 228 may be arranged along the rotation axis 240 and within the lower chamber 236 of the chamber body 300 and fixed in rotation relative to the substrate support 224. The shaft member 230 may be arranged along the rotation axis 240, extend through a passthrough 320 defined within the lower wall 306 of the chamber body 300, and therefrom within a tubulation body 322 (shown in FIG. 5) protruding from the lower wall 306 below the chamber body 300 and substantially coaxial with the rotation axis 240. In certain examples of the present disclosure either (or both) the opaque material 232 and the opaque material 242 may include a carbonaceous material or a ceramic material. Examples of suitable carbonaceous materials include graphite and pyrolytic carbon; examples of suitable ceramic materials include silicon carbide. In accordance with certain examples, either (or both) the support member 228 and the shaft member 230 may be formed from the ceramic material 302.

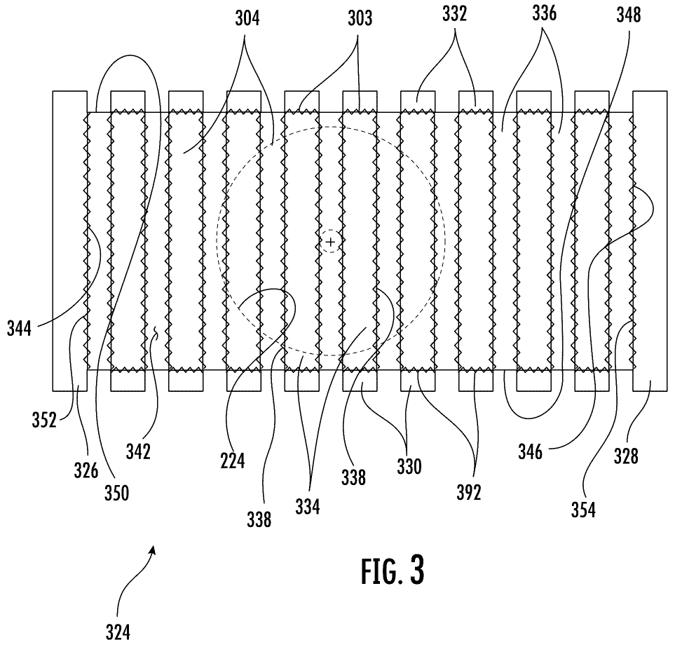

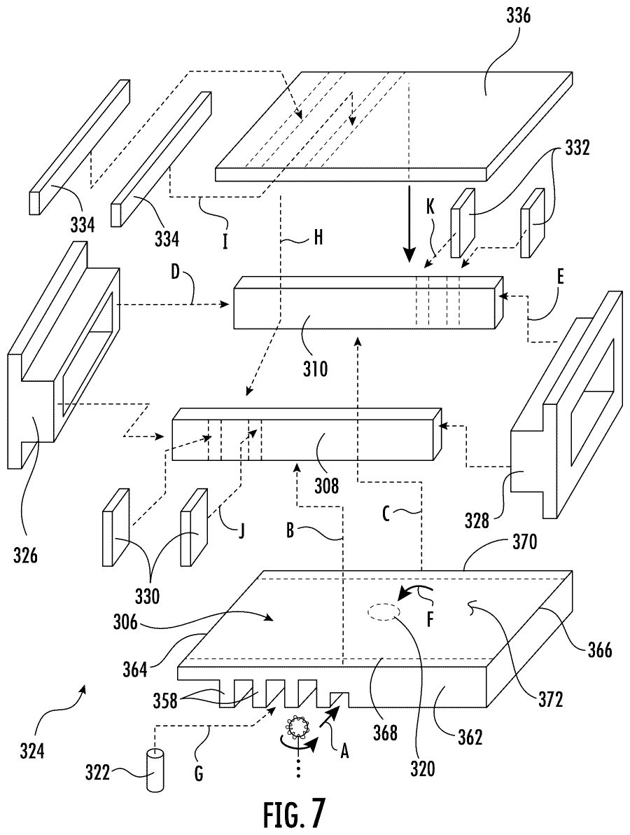

As has been explained above, certain fabrication techniques employed to fabricate chamber bodies may impart artifacts into the structure of the chamber body. For example, welding techniques such as hydrogen (H₂) gas welding may impart residual stress into the weldment formed using the welding technique due to the localized nature of the heating employed to form the weld. Welding techniques may also cause the weldment to deviate dimensionally from the intended geometry of the weldment formed using the welding technique, for example by altering flatness and/or by contour of the resulting fillet formed using the welding technique. Residual stress can stress can generally be relieved using a post-welding annealing operation, albeit at the cost of additional manufacturing cycle time, generally in correspondence with the number of welds that require post-welding anneal. Dimensional deviation may be more resistant to post-welding correction, requiring that dimensional tolerances be widened to reflect the process capability of welding technique employed to fabricate the chamber body and/or greater scrap rates due to dimensional non-conformance. And even then, some material layer deposition processes may be sensitive to welding artifacts, such as welding artifacts imparted into chamber structure optically coupling external heating elements and/or temperature sensors to a substrate during processing. To limit (or eliminate) such artifacts from influence the reliability of the chamber arrangement 200, the chamber body 300 includes a ceramic weldment 324 (shown in FIG. 3) including a lower wall 306 formed from a singular ceramic workpiece 362 (shown in FIG. 7) and defined using a subtractive manufacturing technique to define the lower wall unwelded ribbed region 360 of the chamber body 300.

With reference to FIGS. 3-6, the ceramic weldment 324 is shown. Referring to FIG. 3, the ceramic weldment 324 is shown in a top plan view. It is contemplated that the ceramic weldment 324 include the upper wall 304, the lower wall 306 (shown in FIG. 2), the first sidewall 308 (shown in FIG. 2), and the second sidewall 310 (shown in FIG. 2) of the chamber body 300. It is also contemplated that the ceramic weldment 324 include an inject end flange 326, an exhaust end flange 328, a plurality of first side rib segments 330, and a plurality of second side rib segments 332. Although shown and described herein as including specific elements and having a specific arrangement, it is to be understood and appreciated that the ceramic weldment 324 may include other elements and/or exclude elements shown and described herein as well as different arrangements in other examples and remain within the scope of the present disclosure.

The upper wall 304 includes an upper wall plate 336 and one or more upper rib segment coupled to the upper wall plate 336 by one or more upper rib segment weld, for example a plurality of upper wall rib segments 334 coupled to the upper wall plate 336 by a plurality of upper wall rib segment welds 338. It is contemplated that the upper wall plate 336 have an upper wall interior surface 340 (shown in FIG. 2) and an upper wall exterior surface 342 separated from one another by a thickness of the upper wall plate 336. It is also contemplated that the upper wall plate 336 have an upper wall plate inject edge 344, an upper wall plate exhaust edge 346, an upper wall plate first longitudinal edge 348, and an upper wall plate second longitudinal edge 350. The upper wall interior surface 340 may be substantially planar, extend longitudinally between the upper wall plate inject edge 344 and the upper wall plate exhaust edge 346, and further extends laterally between the upper wall plate first longitudinal edge 348 and the upper wall plate second longitudinal edge 350. The upper wall exterior surface 342 may also be substantially planar in shape and extend longitudinally between the upper wall plate inject edge 344 and the upper wall plate exhaust edge 346. It also contemplated that the upper wall exterior surface 342 extend laterally between the upper wall plate first longitudinal edge 348 and the upper wall plate second longitudinal edge 350.

In certain examples the upper wall plate exhaust edge 346 may be substantially parallel to the upper wall plate inject edge 344. In accordance with certain examples, the upper wall plate second longitudinal edge 350 may be substantially parallel to the upper wall plate first longitudinal edge 348. It is contemplated that the upper wall plate first longitudinal edge 348 may be substantially orthogonal relative to either (or both) the upper wall plate inject edge 344 and the upper wall plate exhaust edge 346. It is also contemplated that the upper wall plate second longitudinal edge 350 may be substantially orthogonal relative to either (or both) the upper wall plate inject edge 344 and the upper wall plate exhaust edge 346. In this respect the wall plate may be substantially rectangular in shape.

The plurality of upper wall rib segments 334 may be coupled to the upper wall exterior surface 342 by the plurality of upper wall rib segment welds 338, extend laterally between the upper wall plate first longitudinal edge 348 and the upper wall plate second longitudinal edge 350, and couple the upper wall plate first longitudinal edge 348 to the upper wall plate second longitudinal edge 350. In the illustrated example the upper wall rib segment 334 is one of nine (9) upper wall rib segments 334 coupled to the upper wall exterior surface 342 by nine (9) upper wall rib segment welds 338. As will be appreciated by those of skill in the art in view of the present disclosure, the upper wall 304 may have fewer or additional of the plurality of the upper wall rib segments 334 and/or upper wall rib segment welds 338 and remain within the scope of the present disclosure. As used herein the term “weld” means a thermal bond, link or structure that joins two elements through a process that involves a softening or melting of a ceramic material within at least one of the elements such that the materials of the elements are secured to each other when cooled, the welded elements thereby being structurally secured to one another as a consequence of the cooling.

The inject end flange 326 is configured to receive thereon the injection flange 202 (shown in FIG. 2) and is also formed from the ceramic material 302 (shown in FIG. 2). It is contemplated that the inject end flange 326 be longitudinally adjacent to the upper wall plate 336, separated from the upper wall plate exhaust edge 346 by the upper wall rib segment 334, and coupled to the upper wall 304 by an inject end flange-to-upper wall plate weld 352. The inject end flange-to-upper wall plate weld 352 in turn extends laterally along the upper wall plate inject edge 344 between the first sidewall 308 (shown in FIG. 2) and the second sidewall 310 (shown in FIG. 2). In certain examples, the inject end flange-to-upper wall plate weld 352 weld may extend continuously and without interruption between the first sidewall 308 and the second sidewall 310, the inject end flange-to-upper wall plate weld 352 in such examples sealably coupling the inject end flange 326 to the upper wall 304 of the ceramic weldment 324. It is contemplated that either of the aforementioned welds may be formed using a hydrogen (H₂) gas welding technique, limiting (or eliminating) risk that contamination be incorporated into the inject end flange-to-upper wall plate weld 352 during the welding process.

The exhaust end flange 328 is configured to receive thereon the exhaust flange 204 (shown in FIG. 2) and is also formed from the ceramic material 302 (shown in FIG. 2). It is contemplated that the exhaust end flange 328 be longitudinally adjacent to the upper wall plate 336, separated from the upper wall plate exhaust edge 346 by the upper wall rib segment 334, and longitudinally opposite the inject end flange 326. The exhaust end flange 328 may further be coupled to the upper wall 304 by an exhaust end flange-to-upper wall plate weld 354, which in turn extends laterally along the upper wall plate exhaust edge 346 and between the first sidewall 308 and the second sidewall 310 at a location longitudinally between the upper wall plate 336 and the exhaust end flange 328. In certain examples, the exhaust end flange-to-upper wall plate weld 354 may extend continuously and without interruption between the first sidewall 308 and the second sidewall 310, the exhaust end flange-to-upper wall plate weld 354 sealably coupling the exhaust end flange 328 to the upper wall 304 of the ceramic weldment 324 in such examples. In accordance with certain examples, the lower wall unwelded ribbed region 360 of the lower wall 306 may longitudinally span the inject end flange-to-upper wall plate weld 352 and the exhaust end flange-to-upper wall plate weld 354. It is also contemplated that either of the aforementioned welds may be formed using a hydrogen (H₂) gas welding technique, limiting (or eliminating) risk of incorporation of non-ceramic inclusion and/or forming voids (e.g., gas bubbles) within the welds.

Referring to FIG. 4, the ceramic weldment 324 is shown in a bottom plan view. In the illustrated example the lower wall 306 of the ceramic weldment 324 has a lower wall plate portion 356 and a lower wall rib portion 358 extending therefrom. It is contemplated that the lower wall 306 be formed from a singular ceramic workpiece 362 (shown in FIG. 7) using a subtractive manufacturing technique, the lower wall 306 thereby defining the lower wall unwelded ribbed region 360. In this respect it is contemplated that the lower wall 306 have a unitary, one-piece construction and be monolithically formed from the ceramic material 302 (shown in FIG. 2) prior to undergoing welding. Advantageously, forming the lower wall 306 using a subtractive manufacturing technique such that the lower wall 306 has a unitary, one-piece construction imparts lateral stiffness to the lower wall 306. The lateral stiffness imparted by the unitary, one-piece construction of the lower wall 306 in turn limits the tendency of the lower wall 306 to distort due to localized heating during welding, for example during coupling of the first sidewall 308 (shown in FIG. 2) and/or the second sidewall 310 (shown in FIG. 2) to the lower wall 306. As will be appreciated by those of skill in the art in view of the present disclosure, this may limit (or eliminate) the need to grind either (or both) the inject end flange 326 and the exhaust end flange 328 subsequent to fabrication in order to correct parallelism of inject end flange 326 relative to the exhaust end flange 328 resultant from heating of the ceramic weldment 324 during fabrication. As used herein the term “unwelded ribbed region” means a unitary, one-piece, construction with no intervening welds and no welding or casting artifacts that may potentially alter the unwelded ribbed region dimensionally or in terms of optical properties.

The lower wall plate portion 356 is similar to the upper wall plate 336 (shown in FIG. 3) and in this respect has a lower wall plate portion inject edge 364, a lower wall plate portion exhaust edge 366, a lower wall plate portion first longitudinal edge 368, and a lower wall plate portion second longitudinal edge 370. The lower wall plate portion inject edge 364 may be longitudinally between the lower wall rib portion 358 of the lower wall 306 and the inject end flange 326. The lower wall plate portion exhaust edge 366 may be separated from the lower wall plate portion inject edge 364 by the lower wall rib portion 358, and a lower wall interior surface 372 (shown in FIG. 2) of the lower wall 306 (shown in FIG. 2) may be substantially parallel to the lower wall plate portion inject edge 364. The lower wall plate portion first longitudinal edge 368 and the lower wall plate portion second longitudinal edge 370 may both extend longitudinally between the lower wall plate portion inject edge 364 and the lower wall plate portion exhaust edge 366, be substantially orthogonal relative to either (or both) the lower wall plate portion first longitudinal edge 368 and the lower wall plate portion second longitudinal edge 370, and be substantially parallel relative to another.

It is contemplated that the lower wall rib portion 358 defines a plurality of lower wall rib segments 374. The plurality of lower wall rib segments 374 may extend laterally between the lower wall plate portion first longitudinal edge 368 and the lower wall plate portion second longitudinal edge 370 and correspond in number and longitudinal position to the plurality of upper wall rib segments 334 (shown in FIG. 3). It is contemplated that the plurality of lower wall rib segments 374 may, in certain examples of the present disclosure, couple the lower wall plate portion first longitudinal edge 368 to the lower wall plate portion second longitudinal edge 370. It is also contemplated that the passthrough 320 be located longitudinally between a pair of the plurality of the lower wall rib segments 374 longitudinally adjacent to one another, that the passthrough 320 extend through the lower wall plate portion 356, and that the passthrough 320 couple a lower wall exterior surface 376 bounded by the lower wall rib portion 358 to the lower wall interior surface 372 (shown in FIG. 2). It is further contemplated that the tubulation body 322 be registered to the passthrough 320 and coupled to the lower wall 306 by a tubulation body-to-lower wall plate portion weld 305, that the lower wall unwelded ribbed region 360 extend about the passthrough 320 at a location where the upper wall rib segment 334 overlays the lower wall unwelded ribbed region 360, and that the lower wall unwelded ribbed region 360 have a width 378 that is greater than 300 millimeters. As will be appreciated by those of skill in the art in view of the present disclosure, sizing the lower wall unwelded ribbed region 360 to be at least 300 millimeters may limit temperature non-uniformity and/or noise in temperature measurements of the substrate support 224 acquired using heater elements and/or external sensors optically coupled to the substrate support 224 by the lower wall 306, such as heater elements and/or pyrometers by way of non-limiting examples.

It is contemplated that the inject end flange 326 be coupled to the lower wall plate portion inject edge 364 by an inject end flange-to-lower wall plate portion weld 380. The inject end flange-to-lower wall plate portion weld 380 may extend between the lower wall plate portion first longitudinal edge 368 and the lower wall plate portion second longitudinal edge 370 of the lower wall plate portion 356. In certain examples, the inject end flange-to-lower wall plate portion weld 380 may extend continuously and without interruption between the lower wall plate portion first longitudinal edge 368 and the lower wall plate portion second longitudinal edge 370, the inject end flange-to-lower wall plate portion weld 380 in turn sealably coupling the inject end flange 326 to the lower wall plate portion 356 of the lower wall 306.

The exhaust end flange 328 may be similarly coupled to the lower wall plate portion exhaust edge 366 by an exhaust end flange-to-lower wall plate portion weld 382. In this respect the exhaust end flange-to-lower wall plate portion weld 382 may extend between the lower wall plate portion first longitudinal edge 368 and the lower wall plate portion second longitudinal edge 370. In certain examples of the present disclosure, the exhaust end flange-to-lower wall plate portion weld 382 may extend continuously and without interruption between the lower wall plate portion first longitudinal edge 368 and the lower wall plate portion second longitudinal edge 370 of the lower wall plate portion 356, the exhaust end flange-to-lower wall plate portion weld 382 sealably coupling the exhaust end flange 328 to the lower wall plate portion 356 of the lower wall 306 in such examples.

Referring to FIG. 5, the ceramic weldment 324 is shown in a first side elevation view. As shown in FIG. 5, the first sidewall 308 couples the upper wall 304 (shown in FIG. 2) of the ceramic weldment 324 to the lower wall 306 (shown in FIG. 2) of the ceramic weldment 324. More specifically, the first sidewall 308 couples the lower wall plate portion 356 (shown in FIG. 4) of the lower wall 306 to the upper wall 304. Specifically, the first sidewall 308 couples the lower wall plate portion 356 of the lower wall 306 to the upper wall plate 336 (shown in FIG. 3) of the upper wall 304. It is contemplated that the first sidewall 308 be coupled to the lower wall plate portion 356 of the lower wall 306 by a first sidewall-to-lower wall plate portion weld 384. It is also contemplated that the first sidewall 308 be coupled to the upper wall plate 336 by a first sidewall-to-upper wall plate weld 386. In certain examples, the first sidewall-to-lower wall plate portion weld 384 may extend continuously and without interruption between the first sidewall 308 and the lower wall plate portion 356, for example at a location bounding the lower wall interior surface 372 (shown in FIG. 2). In accordance with certain examples, the first sidewall-to-upper wall plate weld 386 may extend continuously and within interruption between the first sidewall 308 and the upper wall plate 336, similar at a location bounding the upper wall interior surface 340. As will be appreciated by those of skill in the art, this may seal the interior 316 (shown in FIG. 2) of the chamber body 300 (shown in FIG. 1) from the external environment 8 (shown in FIG. 1) outside of the chamber body 300. It is contemplated that either of the aforementioned welds may be formed using a hydrogen (H₂) gas welding technique, limiting (or eliminating) risk of incorporation of non-ceramic includes and/or voids within the welds.

It is contemplated that the inject end flange 326 and the exhaust end flange 328 be coupled by the first sidewall 308 by welds. In this respect the inject end flange 326 may be coupled to the first sidewall 308 by an inject end flange-to-first sidewall weld 388. In further respect, the exhaust end flange 328 may be coupled to the first sidewall 308 by an exhaust end flange-to-first sidewall weld 390, and the exhaust end flange-to-first sidewall weld 390 may be longitudinally separated from the inject end flange-to-first sidewall weld 388 by the tubulation body 322. In certain examples, the inject end flange-to-first sidewall weld 388 may extend continuously and without interruption between the upper wall plate 336 (shown in FIG. 3) of the upper wall 304 (shown in FIG. 2) and the lower wall plate portion 356 (shown in FIG, 4) of the lower wall 306 (shown in FIG. 4), the inject end flange-to-first sidewall weld 388 thereby separating the interior 316 (shown in FIG. 2) of the chamber body 300 (shown in FIG. 1) from the external environment 8 (shown in FIG. 1). In accordance with certain examples, the exhaust end flange-to-first sidewall weld 390 may similarly extend continuously and without interruption between the upper wall plate 336 and the lower wall plate portion 356 of the lower wall 306 of the ceramic weldment 324, the exhaust end flange-to-first sidewall weld 390 thereby also separating the interior 316 of the chamber body 300 from the external environment 8. It is contemplated that either of the aforementioned welds may be formed using a hydrogen (H₂) gas welding technique, limiting (or eliminating) risk of incorporation of non-ceramic includes and/or voids within the welds.

It is also contemplated that the plurality of first side rib segments 330 be coupled to the ceramic weldment 324 by respective (e.g., individually by one or more) first side rib segment-to-ceramic weldment welds 392 (shown in FIG. 3). In certain examples, one or more of the first side rib segment-to-ceramic weldment welds 392 may couple a singular one of the plurality of first side rib segments 330 to one of the plurality of upper wall rib segments 334. In accordance with certain examples, one or more of the first side rib segment-to-ceramic weldment welds 392 may couple a singular one of the plurality of first side rib segments 330 to a singular one of the plurality of lower wall rib segments 374. In these respects, the plurality of first side rib segment-to-ceramic weldment welds 392 may be as shown and described in U.S. patent application Ser. No. 99/999,999, filed on DATE, the contents of which is incorporated herein by reference in its entirety. It is also contemplated that one or more of the plurality of first side rib segment-to-ceramic weldment welds 392 may extend continuously between one of the plurality of upper wall rib segments 334 and the plurality of lower wall rib segments 374, imparting rigidity into the ceramic weldment 324.

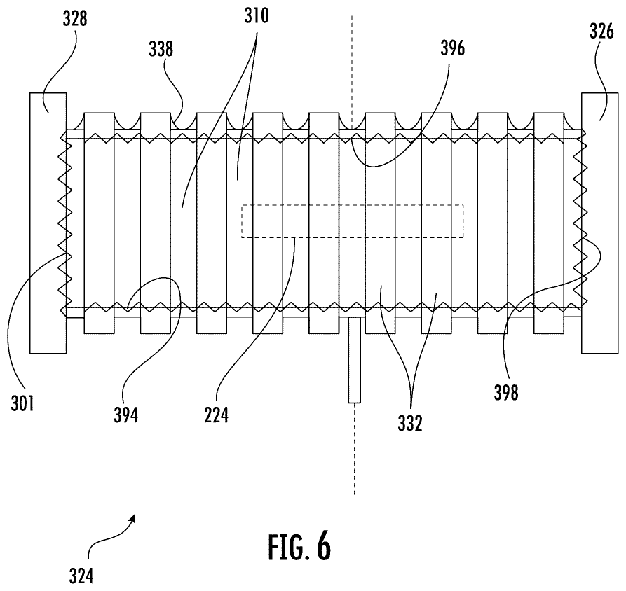

Referring to FIG. 6, the ceramic weldment 324 is shown in a second side elevation view. As shown in FIG. 6, the second sidewall 310 may be similar to the first sidewall 308 (shown in FIG. 2) and in this respect may similarly couple the upper wall 304 (shown in FIG. 2) of the ceramic weldment 324 to the lower wall 306 (shown in FIG. 2) of the ceramic weldment 324. More specifically, the second sidewall 310 may couple the lower wall plate portion 356 (shown in FIG. 4) of the lower wall 306 to the upper wall 304. Specifically, the second sidewall 310 may couple the lower wall plate portion 356 of the lower wall 306 to the upper wall plate 336 (shown in FIG. 3) of the upper wall 304. Coupling may be accomplished by a second sidewall-to-lower wall plate portion weld 394, which may extend in parallel with the first sidewall-to-lower wall plate portion weld 384 (shown in FIG. 5). Coupling may also be accomplished by a second sidewall-to-upper wall plate weld 396, which may similarly extend in parallel with the first sidewall-to-upper wall plate weld 386 (shown in FIG. 5). As above, either (or both) of the second sidewall-to-lower wall plate portion weld 394 and the second sidewall-to-upper wall plate weld 396 may extend continuously and without interruption between the first sidewall 308 and the lower wall plate portion 356, either (or both) separating the interior 316 (shown in FIG. 2) of the chamber body 300 (shown in FIG. 1) from the external environment 8 (shown in FIG. 1) outside of the chamber body 300. Advantageously, the stiffness imparted to lower wall 306 by the subtractive manufacturing process employed to form the lower wall 306 may limit skew among the welds, improving reliability of the ceramic weldment 324 by making it more likely that the ceramic weldment 324 ‘as-built’ conforms dimensionally to the ceramic weldment 324 ‘as-modeled’ with respect to stress imparted by the external environment 8 (shown in FIG. 1) by evacuation of the interior 316 of chamber body 300 during deposition of the material layer 4 (shown in FIG. 1) on to the upper surface 6 (shown in FIG. 1) of the substrate 2 (shown in FIG. 1).

It is contemplated that the inject end flange 326 and the exhaust end flange 328 also be coupled by the second sidewall 310 by welds. In this respect the inject end flange 326 may be coupled to the second sidewall 310 by an inject end flange-to-second sidewall weld 398 and the exhaust end flange 328 may be coupled to the second sidewall 310 by an exhaust end flange-to-second sidewall weld 301. The inject end flange-to-second sidewall weld 398 and the exhaust end flange-to-second sidewall weld 301 may be similar to the inject end flange-to-first sidewall weld 388 and the exhaust end flange-to-first sidewall weld 390, respectively, inject end flange-to-second sidewall weld 398 substantially parallel to the inject end flange-to-first sidewall weld 388 and the exhaust end flange-to-second sidewall weld 301 substantially parallel to the exhaust end flange-to-first sidewall weld 390. Advantageously, the dimensional conformity imparted to the lower wall 306 imparted by the subtractive manufacturing process used to form the lower wall 306 of the ceramic weldment 324 may limit skew of the aforementioned welds to one another, also improving yield of the process used to fabricate the ceramic weldment 324.

The plurality of second side rib segments 332 may be similar to the plurality of first side rib segments 330 (shown in FIG. 5) and this respect may be coupled to the ceramic weldment 324 by respective second side rib segment-to-ceramic weldment welds 303. In this respect it is contemplated that each of the plurality of second side rib segments 332 may cooperate with individual ones of the plurality of upper wall rib segments 334, the plurality of lower wall rib segments 374, and the plurality of first side rib segments 330 to form the external ribs 318 (shown in FIG. 2) of the chamber body 300 (shown in FIG. 1). Advantageously, the dimensional conformity imparted into the lower wall 306 by the subtractive manufacturing process employed to form the lower wall 306 of the ceramic weldment 324 may limit (or eliminate) likelihood of misalignment of the rib segments forming any one of the plurality of external ribs 318, potentially improving yield of the manufacturing process employed to fabricate the ceramic weldment 324. As will be appreciated by those of skill in the art in view of the present disclosure, it can also limit the requisite skill level of the individual performing the weld by reducing (or eliminating) the need to compensate for dimensional non-conformities during the fabrication process.

With reference to FIG. 7, the ceramic weldment 324 is shown being assembled according to an example of the present disclosure. As shown with arrow A, fabrication of the ceramic weldment 324 may begin with forming the lower wall 306 of the ceramic weldment 324 using a subtractive manufacturing technique. Forming the lower wall 306 may be accomplished by defining both the lower wall plate portion 356 and the lower wall rib portion 358 from the singular ceramic workpiece 362, for example using a machining operation. Non-limiting examples of suitable machining operations include milling, boring, grinding, cutting, sawing, and lapping as well as using certain rotary, abrasive tools.

Once the lower wall 306 has been formed, it is contemplated that the first sidewall 308 and the second sidewall 310 may be coupled to the lower wall 306, as shown with arrow B and arrow C. In this respect it is contemplated that the first sidewall 308 be registered to the lower wall interior surface 372 at a location proximate the lower wall plate portion first longitudinal edge 368, and that the first sidewall-to-lower wall plate portion weld 384 (shown in FIG. 5) be formed therealong and longitudinally between the lower wall plate portion inject edge 364 and the lower wall plate portion exhaust edge 366. In further respect, it is also contemplated that the second sidewall 310 be registered to the lower wall interior surface 372 similar at a location proximate the lower wall plate portion second longitudinal edge 370, and that the second sidewall-to-lower wall plate portion weld 394 be formed therealong also longitudinally between the lower wall plate portion inject edge 364 and the lower wall plate portion exhaust edge 366.

As shown with arrow D and arrow E, the inject end flange 326 and the exhaust end flange 328 may thereafter be coupled to the lower wall 306, the first sidewall 308, and the second sidewall 310 of the ceramic weldment 324. In this respect it is contemplated that the inject end flange 326 may be registered to the lower wall plate portion inject edge 364 and the inject end flange-to-lower wall plate portion weld 380 (shown in FIG. 4) formed longitudinally between the inject end flange 326 and the lower wall plate portion inject edge 364, inject end flange-to-lower wall plate portion weld 380 extending laterally between the lower wall plate portion first longitudinal edge 368 and the lower wall plate portion second longitudinal edge 370. In further respect, it is also contemplated that exhaust end flange 328 be registered to the lower wall plate portion 356 at a location longitudinally opposite the inject end flange 326, and that the exhaust end flange-to-lower wall plate portion weld 382 (shown in FIG. 4) be formed at a location longitudinally between the exhaust end flange 328 and the lower wall plate portion exhaust edge 366. It is contemplated that the exhaust end flange-to-lower wall plate portion weld 382 extend laterally between the lower wall plate portion first longitudinal edge 368 and the lower wall plate portion second longitudinal edge 370. The inject end flange-to-first sidewall weld 388 (shown in FIG. 5) and the inject end flange-to-second sidewall weld 398 (shown in FIG. 6) may then be formed between the inject end flange 326 and first sidewall 308 as well as between the inject end flange 326 and the second sidewall 310, respectively. It is contemplated that the exhaust end flange-to-first sidewall weld 390 (shown in FIG. 5) and the exhaust end flange-to-second sidewall weld 301 (shown in FIG. 6) may similarly be formed between the exhaust end flange 328 and the first sidewall 308 as well as between the exhaust end flange 328 and the second sidewall 310, respectively.

As shown with arrow F, it is contemplated that the passthrough 320 be defined within the lower wall 306. In this respect it is contemplated that the passthrough 320 be defined within the lower wall plate portion 356 (shown in FIG. 4) at a location between two (2) longitudinally adjacent one of the plurality of lower wall rib segments 374 (shown in FIG. 4), for example using a drilling and/or a reaming operation, such that the passthrough 320 couples the lower wall exterior surface 376 to the lower wall interior surface 372. More specifically, it is contemplated that the passthrough 320 be defined at location within the lower wall unwelded ribbed region 360 (shown in FIG. 4), and through the lower wall plate portion 356 therein, the couple the lower wall exterior surface 376 (shown in FIG. 4) of the lower wall 306 to the lower wall interior surface 372 of the lower wall 306. As shown with arrow G, the tubulation body 322 may then be registered to the passthrough 320 and the tubulation body-to-lower wall plate portion weld 305 (shown in FIG. 4) formed between the tubulation body 322 and the lower wall plate portion 356. As will be appreciated by those of skill in the art in view of the present disclosure, the subtractive manufacturing process employed to form the lower wall 306 may simplify either (or both) the forming of the passthrough 320 and the forming of the tubulation body-to-lower wall plate portion weld 305 due to stiffness imparted to the lower wall 306 by the single, one-piece composition of the lower wall 306 and the dimensional stability by attributable to absence of welds between the plurality of lower wall rib segments 374 and the lower wall plate portion 356 of the lower wall 306.

As shown with arrow H, coupling of the upper wall plate 336 to the ceramic weldment 324 may be accomplished by registering the upper wall plate 336 to one or more of the upper wall plate 336 coupled to the first sidewall 308, the second sidewall 310, the inject end flange 326, and the exhaust end flange 328, and forming welds between the upper wall plate 336 and ceramic weldment 324. In this respect it is contemplated that the upper wall plate inject edge 344 of upper wall plate 336 may be registered to the inject end flange 326, and the inject end flange-to-upper wall plate weld 352 (shown in FIG. 3) formed, for example at a location whereat the inject end flange-to-upper wall plate weld 352 couples the inject end flange-to-first sidewall weld 388 to the inject end flange-to-second sidewall weld 398. The upper wall plate first longitudinal edge 348 of the upper wall plate 336 may similarly registered to the first sidewall 308 and the first sidewall-to-upper wall plate weld 386 (shown in FIG. 5) formed between the first sidewall 308 and the upper wall plate 336 of the upper wall 304, and upper wall plate second longitudinal edge 350 similarly registered to the second sidewall 310 and the second sidewall-to-upper wall plate weld 396 (shown in FIG. 6) formed between the second sidewall 310 and the upper wall plate 336 of the upper wall 304. It is contemplated that the exhaust end flange 328 may thereafter be registered to the upper wall plate exhaust edge 346, and that the exhaust end flange-to-upper wall plate weld 354 (shown in FIG. 3) formed at a location whereat the exhaust end flange-to-upper wall plate weld 354 couples the exhaust end flange-to-first sidewall weld 390 to the exhaust end flange-to-second sidewall weld 301 (shown in FIG. 6).

Once the upper wall plate 336 has been coupled to the ceramic weldment 324, the plurality of upper wall rib segments 334 may be coupled to the upper wall plate 336. In this respect, as shown with arrow I, the plurality of upper wall rib segments 334 may be sequentially registered to the ceramic weldment 324 and the plurality of upper wall rib segment welds 338 (shown in FIG. 3) formed between the respective upper wall rib segments 334 and the upper wall plate 336. Registration may be accomplished at positions overlying the lower wall rib portion 358, the lower wall rib portion 358 serving as a pre-welding template to inform a fabricator as to where any one of the plurality of upper wall rib segments 334 should be positioned for purposes of welding, and a post-welding indicator of whether the intended position of any one of the plurality of upper wall rib segments 334 was positionally disturbed by the forming of one or more of the plurality of upper wall rib segment welds 338. As will be appreciated by those of skill in the art in view of the present disclosure, this can further limit variation within the ceramic weldment 324 with respect to predetermined position of each of the upper wall rib segments 334, also improving yield of the manufacturing process employed to fabricate the ceramic weldment 324.

As shown with arrow J and arrow K, the plurality of first side rib segments 330 and the plurality of second side rib segments 332 may thereafter be coupled to the ceramic weldment 324. Coupling of the plurality of first side rib segments 330 may be accomplished by registering each of the plurality of first side rib segments 330 at a location whereat each spans a respective one of the plurality of upper wall rib segments 334 and the lower wall rib segments 374, and forming a respective one of the plurality of first side rib segment-to-ceramic weldment welds 392 therebetween. Coupling of the plurality of second side rib segments 332 may similarly be accomplished by registering each of the plurality of second side rib segments 332 at a location whereat each also spans a respective one of the plurality of upper wall rib segments 334 and the lower wall rib segments 374, and thereafter forming a respective one of the plurality of second side rib segment-to-ceramic weldment welds 303 therebetween. Notably, the above-described templating and associated improvement in process capability with respect to position of the plurality of upper wall rib segments 334 may further simplify fabrication of the ceramic weldment 324, also improving yield and/or reducing the requisite skill level otherwise required of the fabricator assembling the ceramic weldment 324.

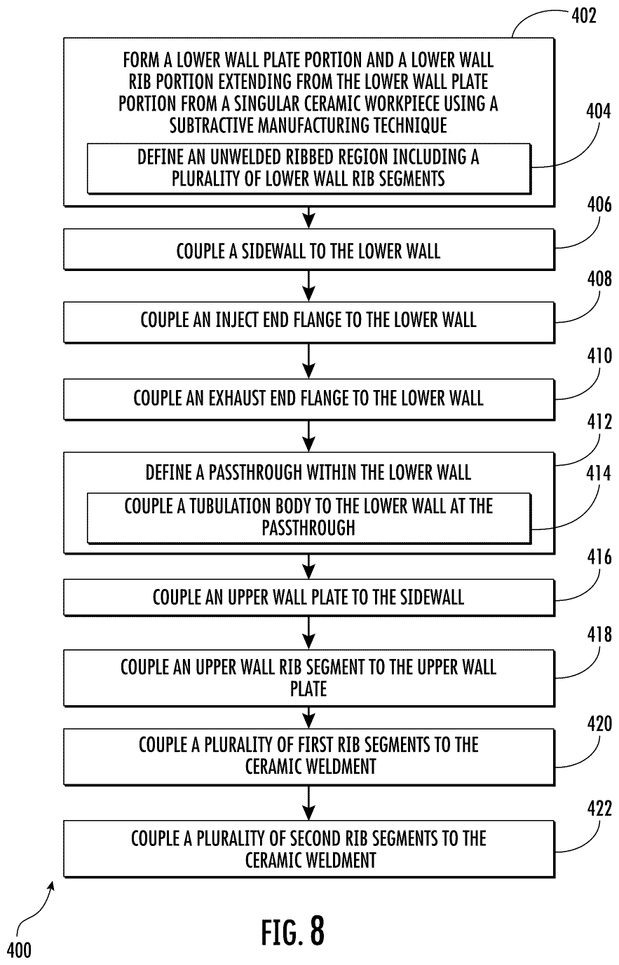

With reference to FIG. 8, a method 400 of making a ceramic weldment, e.g., the ceramic weldment 324 (shown in FIG. 2), is shown. The method 400 generally includes forming a lower wall having a lower wall plate portion and a lower wall ribbed region extending therefrom using a subtractive manufacturing technique, e.g., the lower wall 306 (shown in FIG. 2) having the lower wall plate portion 356 (shown in FIG. 4) and the lower wall rib portion 358 (shown in FIG. 4), as shown with box 402. It is contemplated that forming the lower wall using the subtractive manufacturing technique form (e.g., define) a lower wall unwelded ribbed region along the lower wall, e.g., the lower wall unwelded ribbed region 360 (shown in FIG. 4), as shown with box 404. In certain examples, the subtractive manufacturing technique may include a machining technique, as also shown with box 402. Advantageously, forming the lower wall using the subtractive manufacturing technique may improve time required for fabrication of the ceramic weldment by avoiding the need to couple upper wall rib segments to the ceramic weldment. To further advantage, forming the lower wall using the subtractive manufacturing technique may also limit the requisite skill level of personnel employed to fabricate the ceramic weldment, for example by substituting (at least in part) the repeatability and precision of a computer numerical control process for the experience of an individual skilled welding ceramic material. Unexpectedly, applicant has also found that material layers deposited within ceramic weldments having unwelded ribbed regions may also exhibit less within-material layer variation, believed to be attributable to absence of welding artifacts and distortions within ceramic chambers having welded ribbed regions coupling heater elements and/or optical temperature sensors to the interior of the ceramic weldment. Non-limiting examples of suitable subtractive manufacturing techniques that may be employed to form the ceramic weldment include milling, grinding, lapping and cutting. Non-limiting examples of suitable subtractive manufacturing techniques include milling, grinding, lapping and cutting.

The method 400 may include coupling a first sidewall and a second sidewall to the lower wall, e.g., the first sidewall 308 (shown in FIG. 2) and the second sidewall 310 (shown in FIG. 2), as shown with box 406. The first sidewall may be coupled to the lower wall using a welding technique by forming a first sidewall-to-lower wall plate portion weld, e.g., the first sidewall-to-lower wall plate portion weld 384 (shown in FIG. 5), as also shown with box 406. The second sidewall may be coupled to the lower wall using the welding technique by forming a second sidewall-to-lower wall plate portion weld, e.g., the second sidewall-to-lower wall plate portion weld 394 (shown in FIG. 6), as further shown with box 406. It is contemplated that either (or both) the first sidewall-to-lower wall plate portion weld and the second sidewall-to-lower wall plate portion weld may be formed using a hydrogen (H₂) gas welding technique, as additionally shown with box 406.

The method 400 may also include coupling an inject end flange and an exhaust end flange to the ceramic weldment, e.g., the inject end flange 326 (shown in FIG. 3) and the exhaust end flange 328 (shown in FIG. 3), as shown with box 408 and box 410. The inject end flange may be coupled to the lower wall plate portion by forming an inject end flange-to-lower wall plate portion weld using a welding technique, e.g., the inject end flange-to-lower wall plate portion weld 380 (shown in FIG. 3), as also shown with box 408. The inject end flange may further be coupled to the first sidewall and the second sidewall by forming an inject end flange-to-first sidewall weld and an inject end flange-to-second sidewall weld using the welding technique, e.g., the inject end flange-to-first sidewall weld 388 (shown in FIG. 5) and the inject end flange-to-second sidewall weld 398 (shown in FIG. 6), as further shown with box 408.

The exhaust end flange may be coupled to the lower wall plate portion by forming an exhaust end flange-to-lower wall plate portion weld using a welding technique, e.g., the exhaust end flange-to-lower wall plate portion weld 382 (shown in FIG. 4), as also shown with box 410. The exhaust end flange may further be coupled to the first sidewall and the second sidewall of the ceramic weldment by forming an exhaust end flange-to-first sidewall weld and an exhaust end flange-to-second sidewall weld using the welding technique, e.g., the exhaust end flange-to-first sidewall weld 390 (shown in FIG. 5) and the exhaust end flange-to-second sidewall weld 301 (shown in FIG. 6), as further shown with box 410. It is contemplated that either (or both) the exhaust end flange-to-first sidewall weld and the exhaust end flange-to-second sidewall weld may be formed using a hydrogen (H₂) gas welding technique.

The method 400 may further include defining a passthrough within the lower wall plate of the ceramic weldment, e.g., the passthrough 320 (shown in FIG. 2), as shown with box 412. Once the passthrough is formed, a tubulation body may be coupled to the lower wall at the passthrough, for example the tubulation body 322 (shown in FIG. 5), as shown with box 414. It is contemplated that the passthrough be defined within the lower wall plate portion of the lower wall, as also shown with box 412. It is also contemplated that the tubulation body be coupled to the lower wall plate portion using a tubulation body-to-lower wall plate portion weld, e.g., the tubulation body-to-lower wall plate portion weld 307 (shown in FIG. 5) as also shown with box 414. It is further contemplated that lower wall unwelded ribbed region extend about the passthrough and the tubulation body-to-lower wall plate portion weld. The tubulation body-to-lower wall plate portion weld may be formed using a hydrogen (H₂) gas welding technique, as further shown with box 414.

The method 400 may additionally include coupling an upper wall plate to ceramic weldment, e.g., the upper wall plate 336 (shown in FIG. 3), as shown with box 416. Coupling the upper wall to the ceramic weldment may include forming a first sidewall-to-upper wall plate weld and a second sidewall-to-upper wall plate weld using a welding technique, e.g., the first sidewall-to-upper wall plate weld 386 (shown in FIG. 3) and the second sidewall-to-upper wall plate weld 396 (shown in FIG. 4), as also shown with box 416. Coupling the upper wall to the ceramic weldment may include forming an inject end flange-to-upper wall plate weld and an exhaust end flange-to-upper wall plate weld using the welding technique, e.g., the inject end flange-to-upper wall plate weld 352 (shown in FIG. 3) and the exhaust end flange-to-upper wall plate weld 354 (shown in FIG. 3), as further shown with box 416. Either (or both) of the inject end flange-to-upper wall plate weld and the exhaust end flange-to-upper wall plate weld may be formed using a hydrogen (H₂) gas welding technique.

It is also contemplated that the method 400 may include coupling a plurality of upper wall rib segments to the upper wall, e.g., the plurality of upper wall rib segments 334 (shown in FIG. 3), as shown with box 418. The plurality of upper wall rib segments may be coupled to the upper wall plate by a plurality of upper wall rib segment welds formed using a welding technique, e.g., the plurality of upper wall rib segment welds 338 (shown in FIG. 3) as also shown with box 418. In certain examples the method 400 may also include coupling a plurality of first side rib segments to the ceramic weldment using first side rib segment-to-ceramic weldment welds formed using the welding technique, e.g., the plurality of first side rib segments 330 (shown in FIG. 3) using the plurality of first side rib segment-to-ceramic weldment welds 392 (shown in FIG. 3), as shown with box 420. In accordance with certain examples, the method 400 may further include coupling a plurality of second side rib segments to the ceramic weldment using a plurality of second side rib segment-to-ceramic weldment welds formed using the welding technique, e.g., the plurality of second side rib segments 332 (shown in FIG. 3) using the plurality of second side rib segment-to-ceramic weldment welds 303 (shown in FIG. 3), as shown with box 422. As above, one or more of aforementioned welds may be formed using a hydrogen (H₂) gas welding technique.

Ceramic weldments for chamber bodies may be formed by coupling discrete piece parts to from the ceramic weldment. While generally satisfactory for its intended purpose, welding can be time consuming and may require specialized skill and experience, for example in ceramic weldments where exterior ribs are employed to provide structural support where the ceramic weldment is evacuated due use. Welding also may also entail post-weld annealing to remove residual stress from the ceramic weldment associated with the welding process, adding time and cost the fabrication process. Welding may further introduce dimensional variation and/or variation into the optical properties of the ceramic, potentially limiting yield of the fabrication process employed to make the ceramic weldment and/or, in the case of ceramic weldments employed to deposit material layers onto substrates, induce variation into the material layer due to the influence of the optical variation on the performance of external devices optically coupled through walls of the ceramic weldment.

In examples of the present disclosure, a lower wall of the ceramic weldment is formed using a subtractive manufacturing technique. Forming the lower wall of the ceramic weldment using the subtractive manufacturing technique may limit time required to fabricate the ceramic weldment, for example by limiting time required to otherwise weld discrete piece-part upper rib segments to the ceramic weldment. Forming the lower wall using the subtractive manufacturing technique may limit the requisite level of skill required to fabricate the ceramic weldment, limiting (or eliminating) tendency of the skill level of the fabricators employed to make the ceramic weldment to constrain ceramic weldment fabrication capability. And, in examples wherein the ceramic weldment is employed to deposit materials onto substrates using external devices optically coupled through wall of ceramic weldment, forming the lower wall of the ceramic weldment using the subtractive manufacturing technique may limit variation within the deposited material layers by limiting (or eliminating) dimensional and/or optical property variation potentially imparted into the ceramic weldment by the welding process otherwise employed to attach piece part rib segments to the ceramic weldment.

The term “about” is intended to include the degree of error associated with measurement of the particular quantity based upon the equipment available at the time of filing the application. Operations, to the extent shown and described herein in a specific order in an encompassing method, may be altered in terms of the ordering shown and described herein, and remain within the scope of the present disclosure. Moreover, the methods encompassing the operations shown and described herein may include additional operations and/or exclude certain operations shown and described herein, and remain within the scope of the present disclosure.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the present disclosure has been described with reference to an exemplary embodiment or embodiments, it will be understood by those skilled in the art that various changes may be made and equivalents may be substituted for elements thereof without departing from the scope of the present disclosure. In addition, many modifications may be made to adapt a particular situation or material to the teachings of the present disclosure without departing from the essential scope thereof. Therefore, it is intended that the present disclosure not be limited to the particular embodiment disclosed as the best mode contemplated for carrying out this present disclosure, but that the present disclosure will include all embodiments falling within the scope of the claims.

1. A chamber body, comprising:
a ceramic weldment including:
a lower wall;
a sidewall coupled to the lower wall by a sidewall-to-lower wall weld;
an upper wall plate coupled to the sidewall by a sidewall-to-upper wall weld; and
an upper wall rib segment coupled to the upper wall plate by an upper wall rib segment weld,
wherein the lower wall has a lower wall plate portion and a lower wall rib portion extending therefrom formed from a singular ceramic workpiece using a subtractive manufacturing technique, the lower wall plate portion defining a lower wall unwelded ribbed region including a plurality of lower wall rib segments defined by the lower wall rib portion.

2. The chamber body of claim 1, wherein the upper wall rib segment overlays the lower wall unwelded ribbed region.

3. The chamber body of claim 1, wherein the upper wall rib segment weld overlays the lower wall unwelded ribbed region.

4. The chamber body of claim 1, wherein the ceramic weldment further comprises:
an inject end flange coupled to the lower wall of the ceramic weldment; and
an exhaust end flange coupled to the lower wall of the ceramic weldment, wherein the lower wall unwelded ribbed region separates the exhaust end flange from the inject end flange.

5. The chamber body of claim 4, wherein the inject end flange is coupled to the upper wall plate by an inject end flange-to-upper wall plate weld, wherein the exhaust end flange is coupled to the upper wall plate by an exhaust end flange-to-upper wall plate weld, and wherein the lower wall unwelded ribbed region separates the exhaust end flange-to-upper wall plate weld from the inject end flange-to-upper wall plate weld.

6. The chamber body of claim 5, wherein the lower wall unwelded ribbed region of the lower wall longitudinally spans the inject end flange-to-upper wall plate weld and the exhaust end flange-to-upper wall plate weld.

7. The chamber body of claim 1, wherein the sidewall is a first sidewall and the ceramic weldment further includes a second sidewall coupling the lower wall to the upper wall plate, and wherein the lower wall unwelded ribbed region laterally separates the second sidewall from the first sidewall.

8. The chamber body of claim 7, wherein the first sidewall is coupled to the lower wall plate portion by a first sidewall-to-lower wall plate portion weld, wherein the second sidewall is coupled to the lower wall plate portion by a second sidewall-to-lower wall plate portion weld, and wherein the lower wall unwelded ribbed region couples the second sidewall-to-lower wall plate portion weld to the first sidewall-to-lower wall plate portion weld.

9. The chamber body of claim 8, wherein the upper wall rib segment laterally spans the first sidewall and the second sidewall.

10. The chamber body of claim 8, wherein the upper wall rib segment weld coupling the upper wall rib segment to the upper wall plate laterally spans the first sidewall-to-lower wall plate portion weld and the second sidewall-to-lower wall plate portion weld.

11. The chamber body of claim 1, wherein the lower wall unwelded ribbed region has a width that is greater than at least 300 millimeters.

12. The chamber body of claim 1, wherein the ceramic weldment consists essentially of quartz.

13. A chamber arrangement, comprising:
a chamber body as recited in claim 1, wherein the lower wall defines a passthrough, wherein the ceramic weldment of the chamber body further comprises a tubulation body registered to the passthrough;
a substrate support arranged within an interior of the chamber body and supported for rotation about a rotation axis extending through the passthrough;
a support member arranged along the rotation axis and fixed in rotation relative to the substrate support;
a shaft member arranged along the rotation axis and fixed in rotation relative to the support member;
wherein the shaft member extends through the passthrough; and
wherein the shaft member further extends through the tubulation body and operably couples the substrate support a lift and rotate module.

14. The chamber arrangement of claim 13, wherein the substrate support overlays the lower wall unwelded ribbed region, and wherein the chamber arrangement further includes a pyrometer optically coupled to the substrate support by the lower wall unwelded ribbed region.

15. The chamber arrangement of claim 13, further comprising a lower heater element array including a lower heater element supported below the lower wall of the ceramic weldment, wherein the lower wall unwelded ribbed region optically couples the lower heater element to the substrate support.

16. The chamber arrangement of claim 13, wherein the sidewall is a first sidewall and the ceramic weldment further comprises:
a second sidewall coupling the lower wall to the upper wall plate;
an inject end flange coupled to the lower wall;
an exhaust end flange coupled to the lower wall;
wherein the lower wall unwelded ribbed region laterally separates the second sidewall from the first sidewall; and
wherein the lower wall unwelded ribbed region separates the exhaust end flange from the inject end flange.

17. A semiconductor processing system, comprising:
a chamber arrangement including a chamber body as recited in claim 1, wherein the lower wall unwelded ribbed region has a width that is greater than 300 millimeters;
a precursor source including a silicon-containing material layer precursor coupled to an injection end of the chamber body; and
an exhaust source including a vacuum pump coupled to an exhaust end of the chamber body and therethrough to the precursor source.

18. A method of making a ceramic weldment, comprising:
forming a lower wall having a lower wall plate portion and a lower wall rib portion extending from the lower wall plate portion from a singular ceramic workpiece using a subtractive manufacturing technique;
coupling a sidewall to the lower wall with a sidewall-to-lower wall weld; and
coupling an upper wall plate to the sidewall with a sidewall-to-upper wall weld;
coupling an upper wall rib segment to the upper wall plate with an upper wall rib segment weld; and
whereby the lower wall plate has an unwelded ribbed region including a plurality of lower wall rib segments defined by the lower wall rib portion of the lower wall.

19. The method of claim 18, further comprising defining a passthrough within the lower wall plate portion coupling a lower wall interior surface with a lower wall exterior surface, the passthrough within the lower wall unwelded ribbed region and longitudinally bounded by two lower wall rib segments defined by the lower wall rib portion of the lower wall.

20. The method of claim 18, wherein the subtractive manufacturing technique includes at least one of milling, boring, and sawing.

21. A semiconductor processing system having a chamber arrangement with a chamber body made using the method of claim 18.
